(19) United States
(12) Patent Application Publication
(10) Pub. No.: US 2023/0402357 A1
(43) Pub. Date: Dec. 14, 2023

(54) SEMICONDUCTOR PACKAGE

(71) Applicant: Samsung Electronics Co., Ltd., Suwon-si (KR)

(72) Inventors: JONGBO SHIM, Suwon-si (KR); JI-YONG PARK, Suwon-si (KR)

(21) Appl. No.: 18/133,105

(22) Filed: Apr. 11, 2023

(30) Foreign Application Priority Data
Jun. 13, 2022 (KR) 10-2022-0071704

(51) Int. Cl. H01L 23/498; H01L 23/31; H10B 80/00

(52) U.S. Cl. CPC H01L 23/49811; H01L 23/49822; H01L 23/3128; H10B 80/00; H01L 2224/16227; H01L 24/16

(57) ABSTRACT

A semiconductor package includes a first redistribution substrate, a semiconductor chip on the first redistribution substrate, and vertical conductive structures spaced apart from a side surface of the semiconductor chip. Each of the vertical conductive structures includes a wire, and a metal layer covering a side surface of the wire. A top surface of the wire is exposed from the metal layer.

### CROSS-REFERENCE TO RELATED APPLICATIONS

This U.S. non-provisional patent application claims priority under 35 U.S.C. § 119 to Korean Patent Application No. 10-2022-0071704, filed on Jun. 13, 2022, in the Korean Intellectual Property Office, the entire contents of which are hereby incorporated by reference.

### BACKGROUND OF THE INVENTION

The present disclosure relates to a semiconductor package.

An integrated circuit chip may be realized in the form of a semiconductor package so as to be appropriately applied to an electronic product. In a typical semiconductor package, a semiconductor chip may be mounted on a printed circuit board and may be electrically connected to the printed circuit board through bonding wires or bumps. Various techniques for improving reliability of semiconductor packages and for miniaturizing semiconductor packages have been studied with the development of an electronic industry.

### SUMMARY

Embodiments of the inventive concepts may provide a semiconductor package with improved reliability.

Embodiments of the inventive concepts may also provide a method of manufacturing a semiconductor package, which is capable of increasing the strength of a vertical conductive structure of the semiconductor package while reducing the number of processes of forming the vertical conductive structure.

In an aspect, a semiconductor package may include a first redistribution substrate, a semiconductor chip on the first redistribution substrate, and vertical conductive structures spaced apart from a side surface of the semiconductor chip. Each of the vertical conductive structures may include a wire, and a metal layer covering a side surface of the wire. A top surface of the wire may be exposed from the metal layer.

In an aspect, a semiconductor package may include a first redistribution substrate, a semiconductor chip on the first redistribution substrate, and vertical conductive structures disposed on the first redistribution substrate and spaced apart from a side surface of the semiconductor chip. Each of the vertical conductive structures may include a wire, and a metal layer covering a side surface of the wire. A level of a top surface of the wire may be substantially the same as a level of a top surface of the metal layer.

In an aspect, a semiconductor package may include a first package, and a second package on the first package. The first package may include a first redistribution substrate, a first semiconductor chip and vertical conductive structures on the first redistribution substrate, each of the vertical conductive structures comprising a wire and a metal layer covering a side surface of the wire, a second redistribution substrate spaced apart from the first redistribution substrate with the first semiconductor chip and the vertical conductive structures interposed therebetween, and a first molding member disposed between the first redistribution substrate and the second redistribution substrate and covering a top surface and a side surface of the first semiconductor chip and a side surface of the metal layer. The second package may include a package substrate, a second semiconductor chip on the package substrate, and a second molding member covering a top surface of the package substrate and a top surface and a side surface of the second semiconductor chip. The wire may include a first portion, and a second portion disposed at an end of the first portion. The first portion may have a line shape of which a width is substantially constant as a height in a first direction perpendicular to a top surface of the first redistribution substrate increases, and the second portion may have a shape of which a width decreases as a height in the first direction increases. Another end of the first portion may be in contact with the second redistribution substrate, and the second portion may be in contact with the first redistribution substrate.

### BRIEF DESCRIPTION OF THE DRAWINGS

FIG. 1 is a plan view illustrating a semiconductor package according to example embodiments of the inventive concepts.

FIG. 2 is a cross-sectional view taken along a line I-I′ of FIG. 1.

FIG. 3 is a plan view illustrating a top surface of a vertical conductive structure of FIG. 2.

FIG. 4 is an enlarged view of a portion ‘aa’ of FIG. 2.

FIG. 5 is an enlarged view of the portion ‘aa’ of FIG. 2.

FIG. 6 is an enlarged view of the portion ‘aa’ of FIG. 2.

FIGS. 7A to 7L are cross-sectional views illustrating a method of manufacturing a semiconductor package according to example embodiments of the inventive concepts.

FIG. 8 is a cross-sectional view illustrating a method of manufacturing a semiconductor package according to example embodiments of the inventive concepts.

FIGS. 9A to 9D are cross-sectional views illustrating a method of manufacturing a semiconductor package according to example embodiments of the inventive concepts.

FIGS. 10A and 10B are cross-sectional views illustrating a method of manufacturing a semiconductor package according to example embodiments of the inventive concepts.

### DETAILED DESCRIPTION

Embodiments of the inventive concepts will now be described more fully with reference to the accompanying drawings. Like numbers refer to like elements throughout.

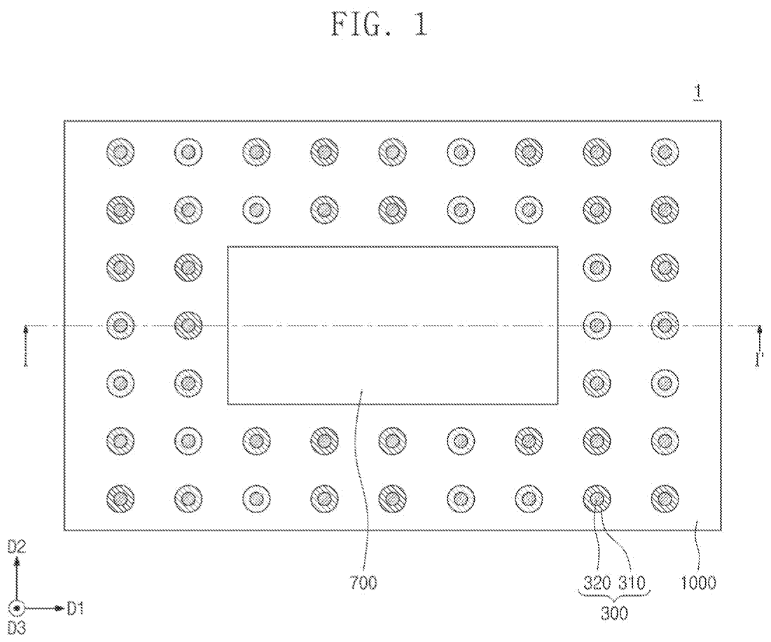

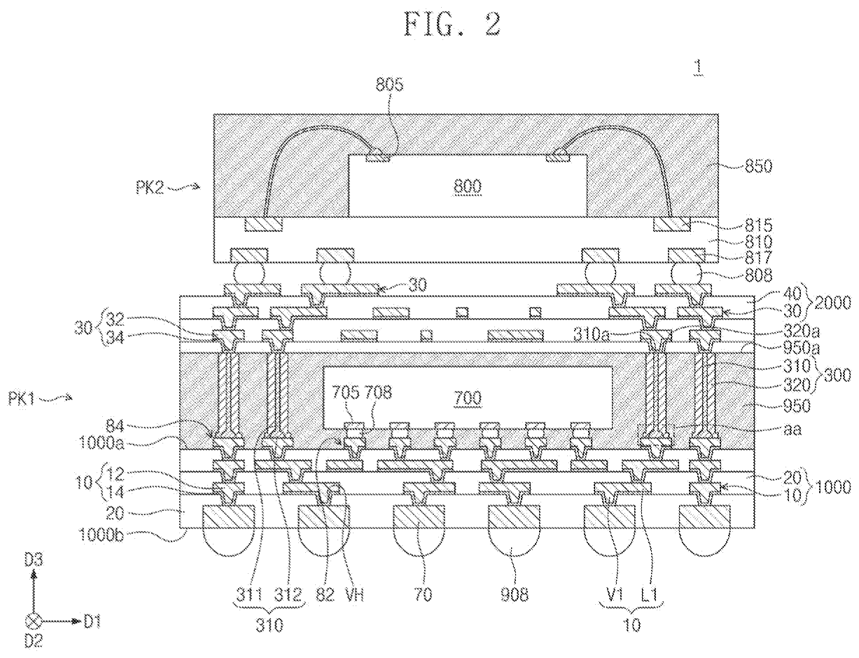

FIG. 1 is a plan view illustrating a semiconductor package according to example embodiments of the inventive concepts. FIG. 2 is a cross-sectional view taken along a line I-I′ of FIG. 1.

Referring to FIGS. 1 and 2, a semiconductor package 1 may include a first semiconductor package PK1 and a second semiconductor package PK2 on the first semiconductor package PK1. The semiconductor package 1 may have a package-on-package (PoP) structure.

The first semiconductor package PK1 may include a first redistribution substrate 1000, a first semiconductor chip 700, a second redistribution substrate 2000, vertical conductive structures 300, and a first molding member 950.

The first redistribution substrate 1000 may have a first surface 1000a and a second surface 1000b, which are opposite to each other. A direction parallel to the first surface 1000a of the first redistribution substrate 1000 may be defined as a first direction D1. A direction which is parallel to the first surface 1000a and is perpendicular to the first direction D1 may be defined as a second direction D2. A direction perpendicular to the first surface 1000a of the first redistribution substrate 1000 may be defined as a third direction D3.

The first redistribution substrate 1000 may include first redistribution patterns 10, first insulating layers 20, and under bump patterns 70. The first redistribution patterns 10 and the under bump patterns 70 may be disposed in the first insulating layers 20. For example, at least one of the first redistribution patterns 10 may be provided in a corresponding one of the first insulating layers 20. Unlike FIG. 2, in some embodiments, the first insulating layers 20 may be a single insulating layer. The first insulating layers 20 may include a photosensitive insulating material. For example, the first insulating layers 20 may include at least one of photosensitive polyimide, polybenzoxazole, a phenol-based polymer, or a benzocyclobutene-based polymer.

The under bump patterns 70 may be disposed at the second surface 1000b of the first redistribution substrate 1000. A bottom surface of each of the under bump patterns 70 may be exposed from the first insulating layer 20. For example, the bottom surface of each of the under bump patterns 70 may be coplanar with a bottom surface of the lowermost first insulating layer 20. The under bump patterns 70 may include copper or aluminum.

The first redistribution patterns 10 may be stacked on the under bump patterns 70. Each of the first redistribution patterns 10 may include a first conductive pattern 12 and a first seed/barrier pattern 14. For example, the first conductive pattern 12 may include copper, and the first seed/barrier pattern 14 may include copper/titanium.

The first seed/barrier pattern 14 may be locally provided on a bottom surface of the first conductive pattern 12. Each of the first redistribution patterns 10 may include a via portion V1 and an interconnection portion L1, which are connected to each other in one body. For example, the via portion V1 and the interconnection portion L1 may be in material continuity with one another.

As used herein, the term “material continuity” may refer to structures, patterns, and/or layers that are formed at the same time and of the same material, without a break in the continuity of the material of which they are formed. As one example, structures, patterns, and/or layers that are in “material continuity” may be homogeneous monolithic structures. As used herein, the term “contact” refers to a direct connection (i.e., touching) unless the context indicates otherwise. For example, when an element is “contacting” or “in contact with” another element, there are no intervening elements present at the point of contact.

The via portion V1 of the first redistribution pattern 10 may fill a via hole VH of the first insulating layer 20 and may be connected to the interconnection portion L1 of another first redistribution pattern 10 thereunder or the under bump pattern 70 thereunder.

First upper pads 82 and second upper pads 84 may be provided on uppermost first redistribution patterns 10 of the first redistribution patterns 10. The first upper pads 82 and the second upper pads 84 may have substantially the same components as the first redistribution patterns 10. In other words, each of the first upper pad 82 and the second upper pad 84 may include the first conductive pattern 12 and the first seed/barrier pattern 14.

The first semiconductor chip 700 may be provided on the first redistribution substrate 1000. For example, the first semiconductor chip 700 may be a logic chip or a memory chip. The first semiconductor chip 700 may be disposed on the first redistribution substrate 1000 in such a way that a first chip pad 705 of the first semiconductor chip 700 faces the first redistribution substrate 1000.

A connection terminal 708 may be in contact with the first upper pad 82 and the first chip pad 705 and may be electrically connected to the first chip pad 705 and the first upper pad 82. The first semiconductor chip 700 may be electrically connected to the first redistribution substrate 1000 through the connection terminal 708. The connection terminal 708 may include at least one of a solder, a pillar, or a bump. The connection terminal 708 may include a conductive material such as tin (Sn) or silver (Ag).

The vertical conductive structures 300 may be disposed on the first surface 1000a of the first redistribution substrate 1000 and may be spaced apart from a side surface of the first semiconductor chip 700 in the first direction D1 and/or the second direction D2. The vertical conductive structures 300 may be arranged in the first direction D1 and the second direction D2 and may be spaced apart from each other. The vertical conductive structures 300 will be described later in more detail.

The second redistribution substrate 2000 may be disposed on a top surface of the first molding member 950 and a top surface of the vertical conductive structure 300.

The second redistribution substrate 2000 may include a second insulating layer 40 and a second redistribution pattern 30. The second insulating layer 40 may include a plurality of second insulating layers 40 and the second redistribution pattern 30 may include a plurality of second redistribution patterns 30, where at least one of the plurality of second redistribution patterns 30 is provided in each of the plurality of second insulating layers 40. The vertical conductive structure 300 may be connected to the second redistribution pattern 30. For example, a lowermost second redistribution pattern 30 may contact upper surfaces of the vertical conductive structures 300. The second insulating layers 40 may be the same/similar photosensitive insulating layer as the first insulating layer 20. In example embodiments, the second insulating layers 40 may include a photosensitive insulating material. For example, the second insulating layers 40 may include at least one of photosensitive polyimide, polybenzoxazole, a phenol-based polymer, or a benzocyclobutene-based polymer.

The second redistribution patterns 30 may include a second conductive pattern 32 and a second seed/barrier pattern 34. The second conductive pattern 32 and the second seed/barrier pattern 34 may include the same/similar materials as the first conductive pattern 12 and the first seed/barrier pattern 14, respectively. For example, the second conductive pattern 32 may include copper, and the second seed/barrier pattern 34 may include copper/titanium. Like the first redistribution pattern 10, the second redistribution pattern 30 may have a via portion V1 and an interconnection portion L1 connected thereto. For example, the via portion V1 and the interconnection portion L1 of the second redistribution pattern 30 may be in material continuity with one another.

The second semiconductor package PK2 may be provided on the second redistribution substrate 2000. The second semiconductor package PK2 may include a package substrate 810, a second semiconductor chip 800, and a second molding member 850. The package substrate 810 may be a printed circuit board or a redistribution substrate. Metal pads 815 and 817 may be provided on both surfaces of the package substrate 810. For example, metal pads 815 may be provided on an upper surface of the package substrate 810, and metal pads 817 may be provided on a lower surface of the package substrate 810. The second semiconductor chip 800 may be a memory chip such as a DRAM chip or a NAND FLASH chip. Alternatively, the second semiconductor chip 800 may be a logic chip. The second semiconductor chip 800 may be a semiconductor chip of which a kind is different from that of the first semiconductor chip 700. For example, a second chip pad 805 disposed on one surface of the second semiconductor chip 800 may be connected to the metal pad 815 of the package substrate 810 by a wire bonding method.

A package connection terminals 808 may be disposed between the first semiconductor package PK1 and the second semiconductor package PK2. The package connection terminals 808 may be in contact with an uppermost second redistribution pattern of the second redistribution patterns 30 and the metal pads 817. The package connection terminals 808 may be electrically connected to the second redistribution pattern 30 and the metal pads 817. Thus, the second semiconductor package PK2 may be electrically connected to the first semiconductor chip 700 and external connection terminals 908 through the package connection terminals 808, the second redistribution substrate 2000, the vertical conductive structure 300, and the first redistribution substrate 1000.

The vertical conductive structures 300 may be disposed on the second upper pads 84, contacting upper surfaces of the second upper pads 84. Each of the vertical conductive structures 300 may include a wire 310 and a metal layer 320, which extend lengthwise in the third direction D3. The metal layer 320 may cover a side surface of the wire 310, contacting the side surface of the wire 310. The wire 310 and the metal layer 320 may include a first metal material and a second metal material, respectively. The first metal material and the second metal material may be different metal materials or the same metal material. For some examples, the first metal material may include at least one of gold, silver, or aluminum, and the second metal material may include copper. For certain examples, the first metal material and the second metal material may include copper. In embodiments in which the wire 310 and the metal layer 320 include the same metal material, a grain size and a crystal direction of the wire 310 may be different from those of the metal layer 320. As described later, this may be because the wire 310 is elongated in one direction in a formation process and the metal layer 320 is formed by an electroplating process.

The wire 310 may include a first portion 311 and a second portion 312 connected to an end of the first portion 311. The first portion 311 may have a line shape, and the second portion 312 may have a hemisphere shape or a hemisphere-like shape. Alternatively, the second portion 312 may have a shape of which a width decreases as a vertical height from the first surface 1000a of the first redistribution substrate 1000 increases. A width of the first portion 311 may be substantially constant as a height in the third direction D3 increases. A diameter of the second portion 312 may be greater than the width of the first portion 311.

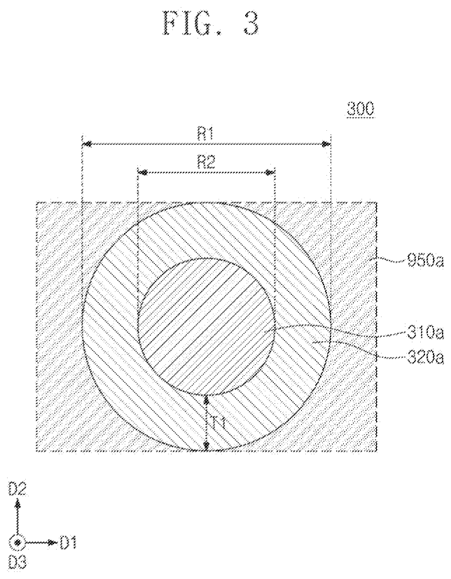

FIG. 3 is a plan view illustrating a top surface of a vertical conductive structure of FIG. 2.

Referring to FIGS. 2 and 3, the top surface of the vertical conductive structure 300 may be exposed from a top surface 950a of the first molding member 950. In addition, a top surface 310a of the wire 310 may be exposed from a top surface 320a of the metal layer 320. Electrical characteristics (e.g., conductivity) of the wire 310 may be better than those of the metal layer 320 due to the material (e.g., Au v. Cu) and crystallinity of the wire 310. The wire 310 may be connected directly to the first redistribution pattern 10 and the second redistribution pattern 30, and thus electrical characteristics (e.g., conductivity) of the semiconductor package 1 may be improved. The top surface 950a of the first molding member 950, the top surface 310a of the wire 310 and the top surface 320a of the metal layer 320 may be substantially coplanar with each other. For example, a level of the top surface 310a of the wire 310 may be substantially the same as a level of the top surface 320a of the metal layer 320. A height of the wire 310 may be substantially equal to a height of the metal layer 320. The height of the wire 310 and the height of the metal layer 320 may mean lengths in the third direction D3 from a top surface of the second upper pad 84.

The top surface of the vertical conductive structure 300 exposed from the first molding member 950 may have a circular shape or a circle-like shape. The exposed top surface 310a of the wire 310 may have a circular shape or a circle-like shape. The exposed top surface 320a of the metal layer 320 may have a ring shape.

A diameter R1 of the vertical conductive structure 300 may range from 80 μm to 120 μm when viewed in a plan view. A diameter R2 of the wire 310 may range from 40 μm to 60 μm when viewed in a plan view. The diameter R2 of the wire 310 may correspond to the width of the first portion 311 of the wire 310.

A width T1 of the metal layer 320 may range from 40 μm to 60 μm when viewed in a plan view. The diameter R2 of the wire 310 and the width T1 of the metal layer 320 may be variously adjusted depending on a design.

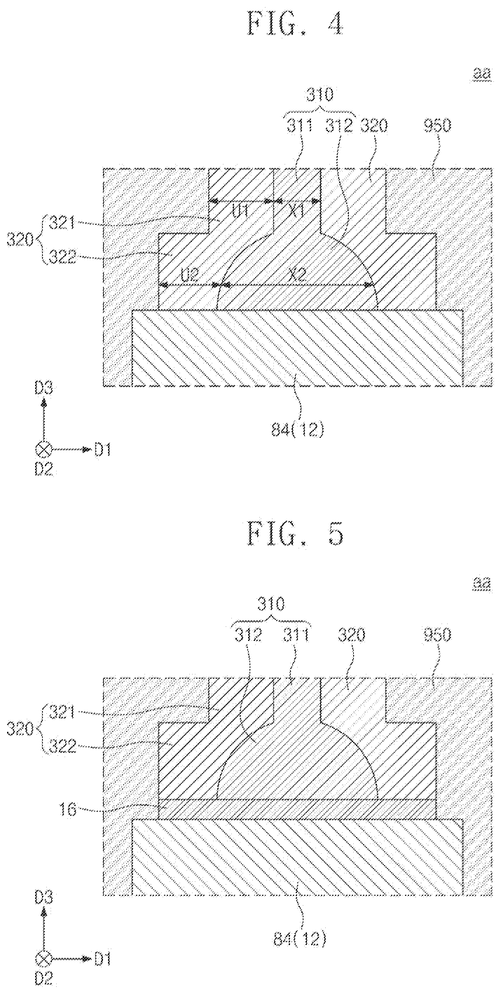

FIG. 4 is an enlarged view of a portion ‘aa’ of FIG. 2.

Referring to FIGS. 2 and 4, the second portion 312 of the wire 310 may be in contact with the first conductive pattern 12 of the second upper pad 84. The metal layer 320 may also be in contact with the first conductive pattern 12 of the second upper pad 84. For example, an upper surface of the first conductive pattern 12 of the second upper pad 84 may contact the entire lower surface of the second portion 312 of the wire 310 and the entire lower surface of the metal layer 320. The metal layer 320 and the first conductive pattern 12 may include the same metal material. For example, the metal layer 320 and the first conductive pattern 12 may include copper.

In some embodiments, a metal pattern (not shown) for improving diffusion prevention and adhesive strength may be additionally disposed between the first conductive pattern 12 of the second upper pad 84 and the second portion 312 of the wire 310 and between the first conductive pattern 12 of the second upper pad 84 and the metal layer 320. The metal pattern may include at least one of gold or nickel.

The metal layer 320 may include an extension 321 covering the first portion 311 of the wire 310, and a protrusion 322 covering the second portion 312 of the wire 310. The protrusion 322 may be disposed at an end of the extension 321 and may have a shape protruding from the extension 321 in the first direction D1 and the second direction D2.

In some embodiments, a surface of the extension 321 and a surface of the protrusion 322 may have profiles similar to those of surfaces of the first and second portions 311 and 312 of the wire 310, respectively.

A thickness U1 of the extension 321 of the metal layer 320 may be less than, equal to or greater than a thickness U2 of the protrusion 322. On the other hand, a diameter X1 of the first portion 311 of the wire 310 may be always less than a diameter X2 of the second portion 312. A difference between the thickness U1 of the extension 321 of the metal layer 320 and the thickness U2 of the protrusion 322 may be less than a difference between the diameter X1 of the first portion 311 of the wire 310 and the diameter X2 of the second portion 312. The diameter X1 of the first portion 311 of the wire 310 may correspond to the diameter R2 of the exposed top surface 310a of the wire 310, and the thickness U1 of the extension 321 of the metal layer 320 may correspond to the width T1 of the exposed top surface 320a of the metal layer 320 of FIG. 3.

FIG. 5 is an enlarged view corresponding to the portion ‘aa’ of FIG. 2.

Referring to FIGS. 2 and 5, a seed pattern 16 may be disposed between the first conductive pattern 12 of the second upper pad 84 and the second portion 312 of the wire 310 and between the first conductive pattern 12 of the second upper pad 84 and the metal layer 320. The seed pattern 16 may include copper. A bottom surface of the second portion 312 of the wire 310 and a bottom surface of the metal layer 320 may be in contact with a top surface of the seed pattern 16.

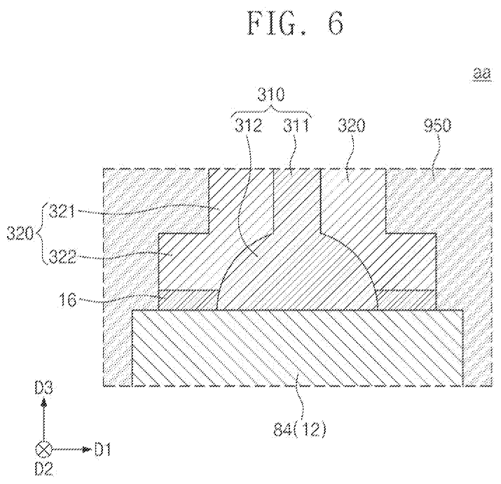

FIG. 6 is an enlarged view corresponding to the portion ‘aa’ of FIG. 2.

Referring to FIGS. 2 and 6, the second portion 312 of the wire 310 may be in contact with a top surface of the first conductive pattern 12 of the second upper pad 84. The seed pattern 16 may be disposed between the metal layer 320 and the first conductive pattern 12 of the second upper pad 84. The seed pattern 16 may be in contact with a side surface of the second portion 312 of the wire 310. A lowermost portion of the wire 310 may be disposed below an uppermost portion of the seed pattern 16.

Referring again to FIG. 2, a thickness of the first semiconductor chip 700 should have a certain value or more to improve heat dissipation characteristics of the semiconductor package 1 or the first semiconductor package PK1. In this case, the vertical conductive structure 300 may be required to have a height greater than the thickness of the first semiconductor chip 700.

According to the embodiments of the inventive concepts, the vertical conductive structure 300 may include the wire 310 and the metal layer 320 covering the side surface of the wire 310. A length of the wire 310 may be adjusted using a wire control apparatus to have a great height, and the metal layer 320 may reinforce strength of the wire 310. As a result, even though the thickness of the first semiconductor chip 700 is increased, strength of the vertical conductive structure 300 may be increased while easily increasing the height of the vertical conductive structure 300, and thus reliability of the semiconductor package may be improved.

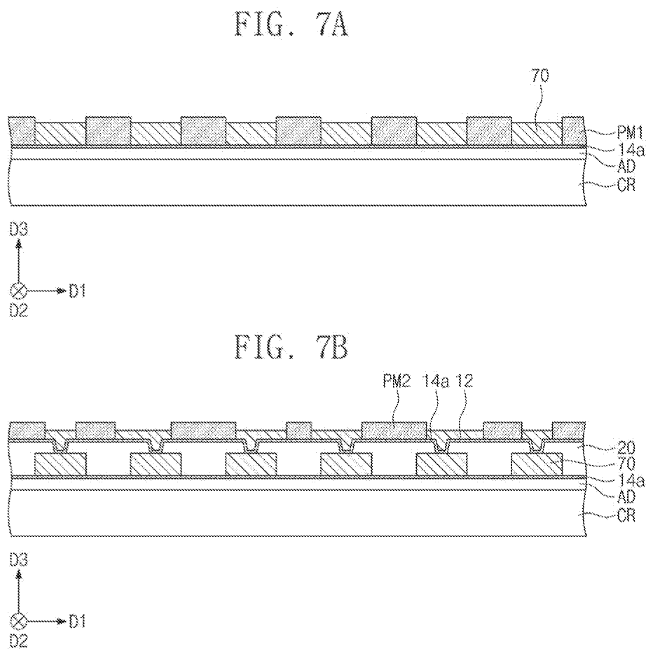

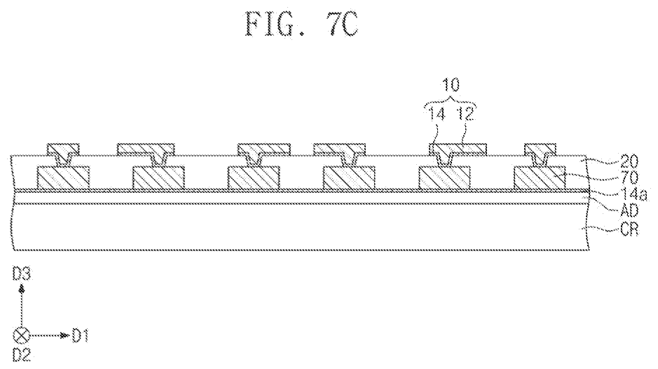

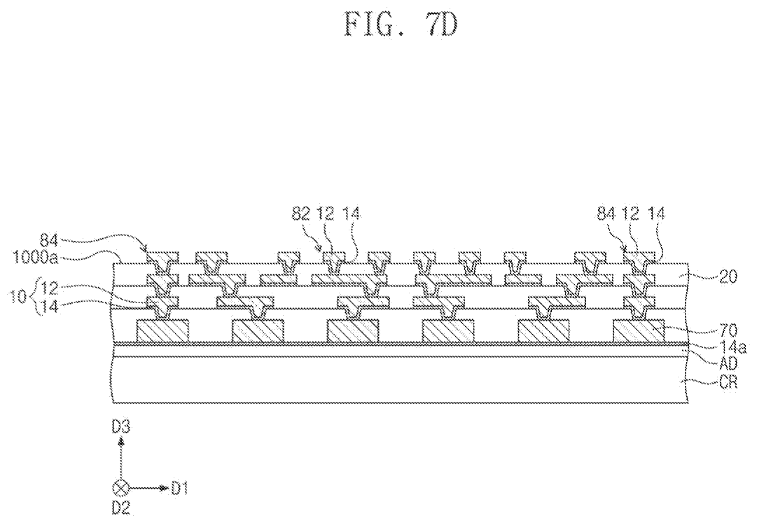

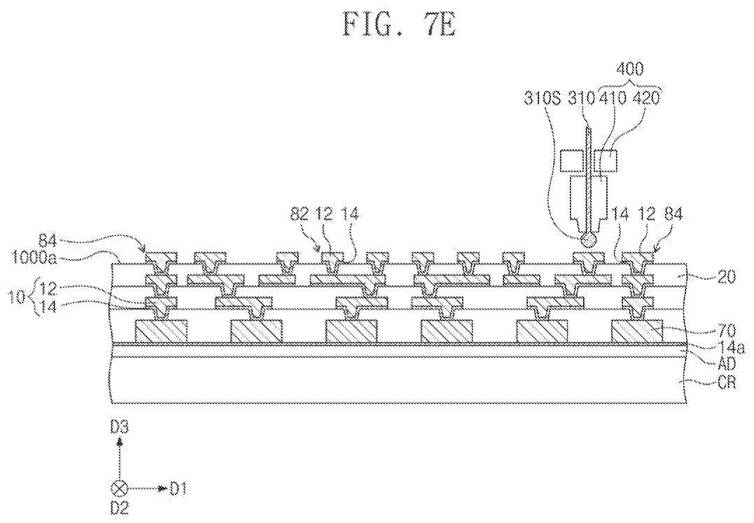

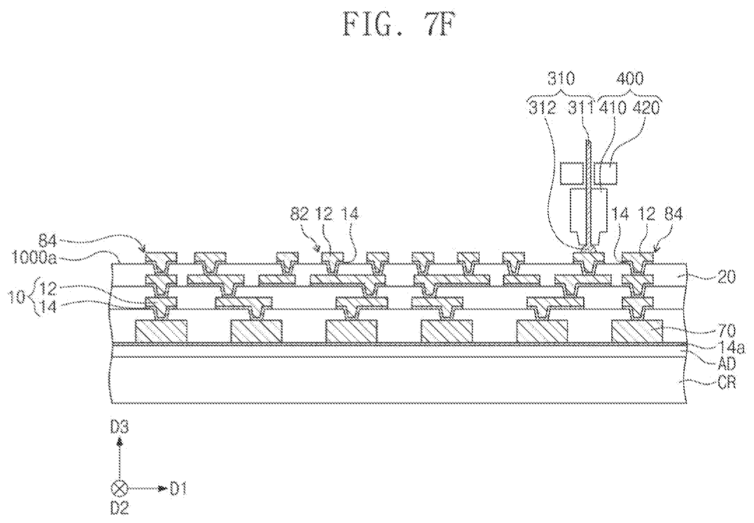

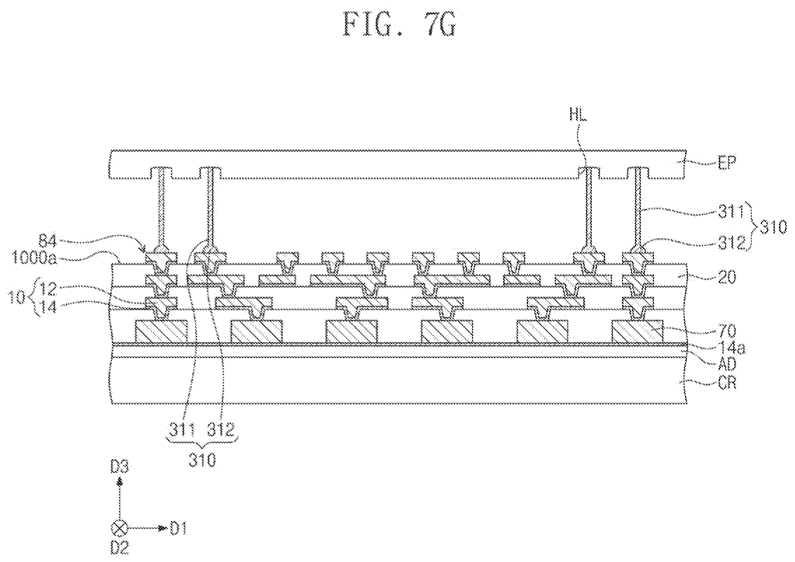

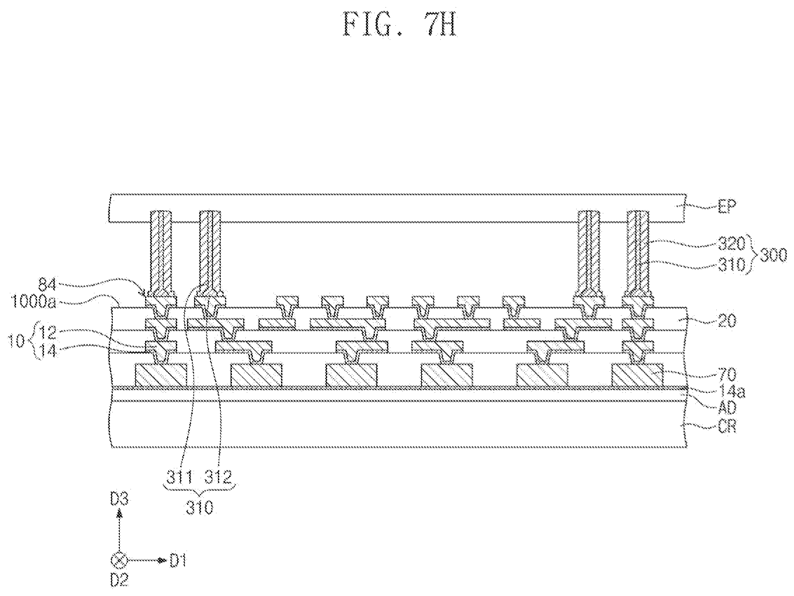

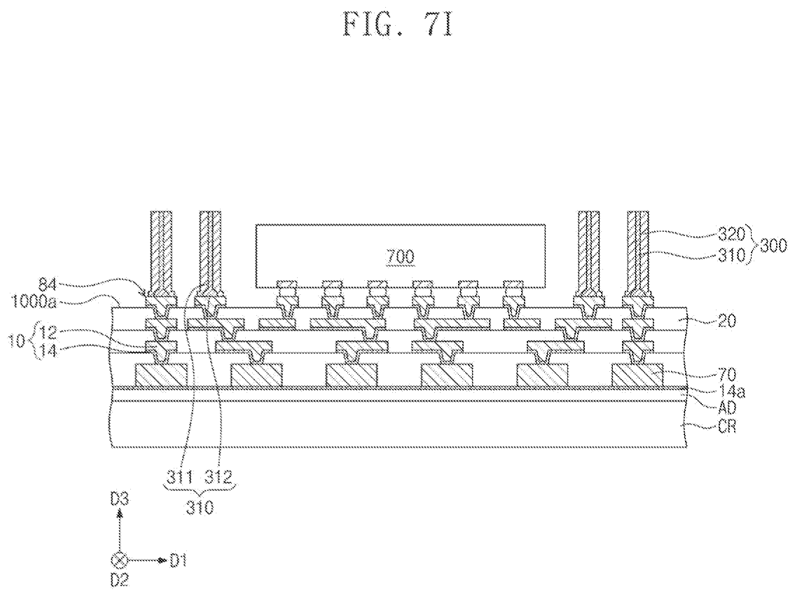

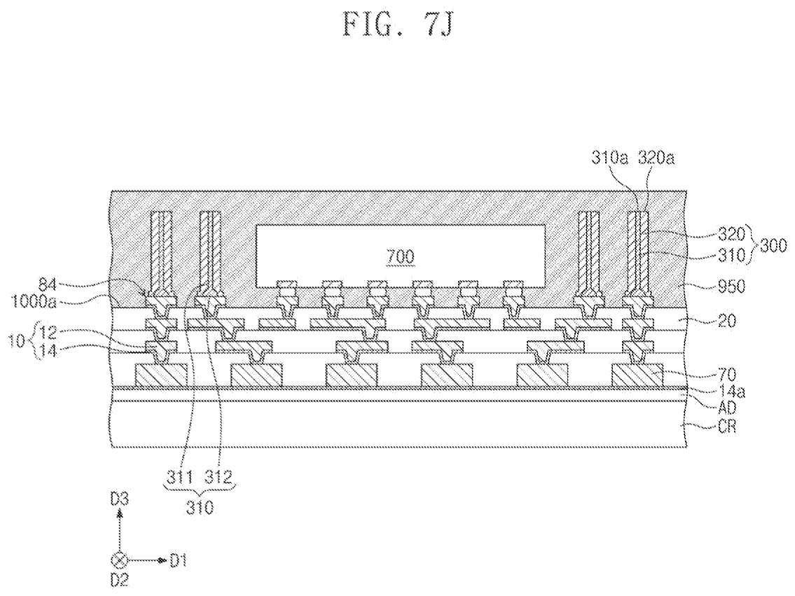

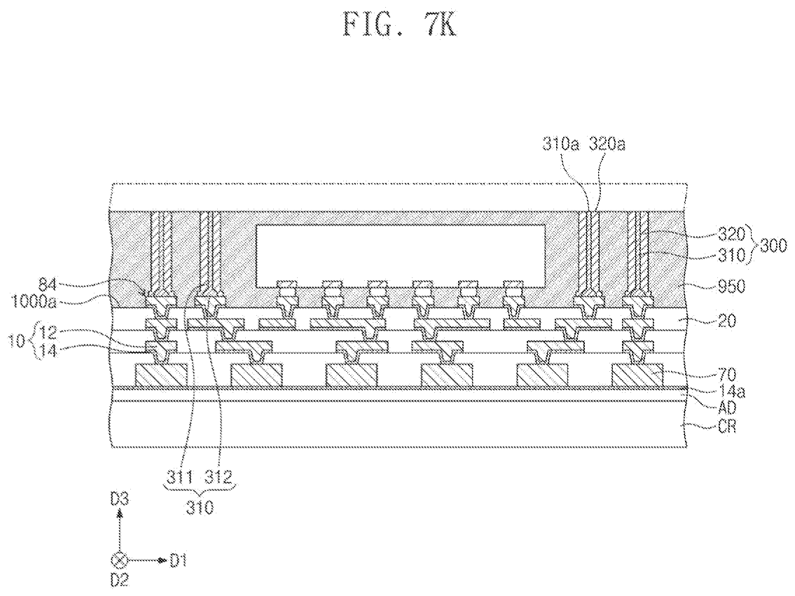

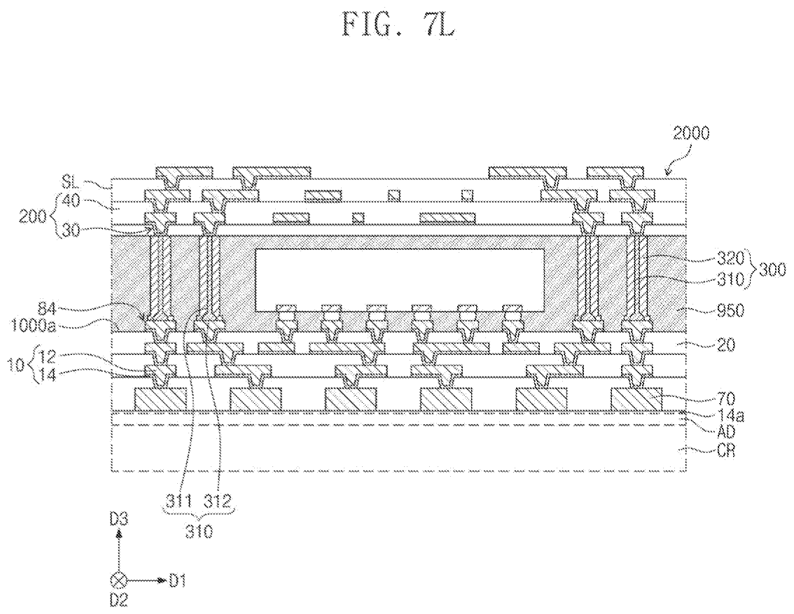

FIGS. 7A to 7L are cross-sectional views illustrating a method of manufacturing a semiconductor package according to example embodiments of the inventive concepts. Hereinafter, the descriptions to the same features as mentioned above with reference to FIGS. 1 to 6 will be omitted for the purpose of ease and convenience in explanation.

Referring to FIG. 7A, a carrier substrate CR having a surface on which an adhesive layer AD is formed may be provided. A seed/barrier layer 14a may be formed on the carrier substrate CR to cover a top surface of the adhesive layer AD. The seed/barrier layer 14a may be formed using a deposition process. For example, the seed/barrier layer 14a may include copper/titanium (Cu/Ti). The adhesive layer AD may adhere the seed/barrier layer 14a to a top surface of the carrier substrate CR.

A first photomask pattern PM1 may be formed on a top surface of the seed/barrier layer 14a. The first photomask pattern PM1 may include openings defining spaces in which under bump patterns 70 will be formed. The first photomask pattern PM1 may be formed through a process of forming a photoresist layer, an exposure process, and a development process. A portion of the seed/barrier layer 14a may be exposed by the first photomask pattern PM1. The under bump patterns 70 may be formed by an electroplating process using the seed/barrier layer 14a in the openings as an electrode.

Referring to FIG. 7B, the first photomask pattern PM1 may be removed. Next, a first insulating layer 20 may be formed to cover the under bump patterns 70. The first insulating layer 20 may be formed by, for example, a spin-coating process and then may be patterned by exposure and development processes to have an opening exposing at least a portion of a top surface of each of the under bump patterns 70. Subsequently, a hardening process of the first insulating layer 20 may be performed. A seed/barrier layer 14a may be formed again on the first insulating layer 20. A second photomask pattern PM2 including openings may be formed on the seed/barrier layer 14a. Next, a first conductive pattern 12 may be formed on the seed/barrier layer 14a by an electroplating process using the seed/barrier layer 14a as an electrode.

Referring to FIG. 7C, the second photomask pattern PM2 may be removed. Next, a portion of the seed/barrier layer 14a exposed from the first conductive pattern 12 may be removed to form a first seed/barrier pattern 14. For example, the portion of the seed/barrier layer 14a not covered by the first conductive pattern 12 may be removed. Thus, a first redistribution pattern 10 including the first conductive pattern 12 and the first seed/barrier pattern 14 may be formed.

Referring to FIG. 7D, the aforementioned method of forming the first insulating layer 20 and the first redistribution pattern 10 may be repeatedly performed to sequentially stack the first insulating layers 20 and the first redistribution patterns 10. First upper pads 82 and second upper pads 84 may be formed by the same method as the first redistribution patterns 10.

Referring to FIGS. 7E and 7F, a wire bonding process may be performed. Like FIG. 7E, a wire 310 may be disposed on the second upper pad 84. The wire 310 may be disposed on the second upper pad 84 by a wire control apparatus 400 which is moveable and capable of adjusting a length of the wire 310.

The wire control apparatus 400 may include a wire spool, a wire tensioner system (not illustrated), a wire clamp 420, a capillary 410, and an electric-flame-off (EFO) (not illustrated). The wire control apparatus 400 may be a known wire control apparatus.

The wire 310 may pass through a central portion of the capillary 410 to make a tail protruding from the capillary 410, and a strong spark may be applied from the EFO to the tail to form a ball shape 310S at an end of the wire 310. A diameter of the ball shape 310S may be greater than a width of the wire 310.

Like FIG. 7F, the ball shape 310S of the wire 310 may be adhered to a top surface of the second upper pad 84, and external force may be applied thereto. A shape of the ball shape 310S may be adjusted by a combination of the external force, heat, and ultrasonic waves. A length of the wire 310 may be adjusted using the capillary 410 again, and then, the wire 310 may be cut. As a result, the wire 310 may be formed to have a first portion 311 extending in a vertical direction and a second portion 312 connected to an end of the first portion 311.

Referring to FIG. 7G, the wire bonding process may be sequentially performed on the second upper pads 84 disposed on a top surface 1000a of the first redistribution substrate 1000. An electrode substrate EP including a plurality of holes HL may be provided on the wires 310. Upper portions of the wires 310 may be disposed in the holes HL of the electrode substrate EP, respectively, and the wires 310 may be in direct contact with or electrically connected to the electrode substrate EP.

Referring to FIG. 7H, the wire 310 may be electroplated with a metal material by using the electrode substrate EP as an electrode. For example, the metal material may be copper. As a result, a metal layer 320 covering a side surface of the wire 310 may be formed, and a vertical conductive structure 300 including the wire 310 and the metal layer 320 may be formed. The metal layer 320 may be uniformly formed on the side surface of the wire 310, but in certain embodiments, a thickness of the metal layer 320 on the first portion 311 of the wire 310 may be different from a thickness of the metal layer 320 on the second portion 312 of the wire 310. A top surface of the wire 310 may be exposed or unexposed from the metal layer 320.

Referring to FIG. 7I, the electrode substrate EP may be removed, and a first semiconductor chip 700 may be mounted on the first redistribution substrate 1000 in such a way that a first chip pad 705 of the first semiconductor chip 700 faces the first redistribution substrate 1000. The process of mounting the first semiconductor chip 700 on the first redistribution substrate 1000 may be performed using a thermocompression process.

Referring to FIG. 7J, a first molding member 950 may be formed to cover the top surface 1000a of the first redistribution substrate 1000 and a top surface and a side surface of the first semiconductor chip 700 and to fill a space between a bottom surface of the first semiconductor chip 700 and the first redistribution substrate 1000. The first molding member 950 may be formed to cover the top surface 310a of the wire 310 and the top surface 320a of the metal layer 320.

Referring to FIG. 7K, a planarization process may be performed on the first molding member 950. The planarization process may be performed until the top surface 310a of the wire 310 and the top surface 320a of the metal layer 320 are exposed. By the planarization process, a top surface of the first molding member 950, the top surface 310a of the wire 310 and the top surface 320a of the metal layer 320 may be substantially coplanar with each other. The molding member 950 may be spaced apart from the wire 310 in the first and second direction D1 and D2. For example, the metal layer 320 may be provided between the wire 310 and the molding member 950.

Referring to FIG. 7L, a second redistribution substrate 2000 may be formed on the first molding member 950 and the vertical conductive structures 300. The second redistribution substrate 2000 may be formed by substantially the same method as the aforementioned method of forming the first redistribution substrate 1000. The second redistribution pattern 30 may be formed to be connected to the vertical conductive structure 300. A singulation process may be performed along a sawing line SL in the third direction D3 to form a first semiconductor package PK1. Next, the carrier substrate CR, the adhesive layer AD and the seed/barrier layer 14a may be removed. The removal of the seed/barrier layer 14a may be performed using an etching process. The under bump patterns 70 may be exposed by the removal of the seed/barrier layer 14a.

Referring again to FIG. 2, external connection terminals 908 may be formed on the exposed under bump patterns 70 to manufacture the first semiconductor package PK1. Next, a second semiconductor package PK2 may be mounted on the first semiconductor package PK1.

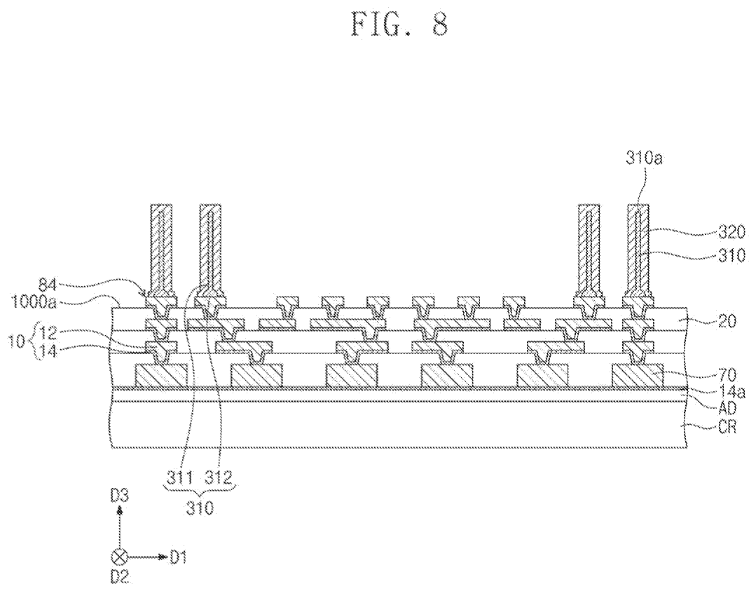

FIG. 8 is a cross-sectional view illustrating a method of manufacturing a semiconductor package according to example embodiments of the inventive concepts.

Referring to FIGS. 7H and 8, in the electroplating process, the metal layer 320 may cover the top surface 310a of the wire 310, depending on a contact method. Subsequent processes may be the same as described above, and the planarization process of FIG. 7K may be performed until the top surface 310a of the wire 310 is exposed.

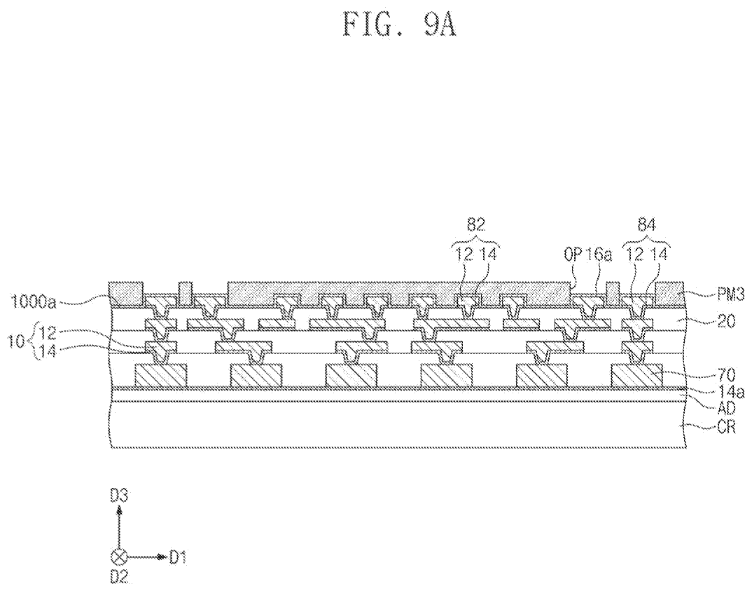

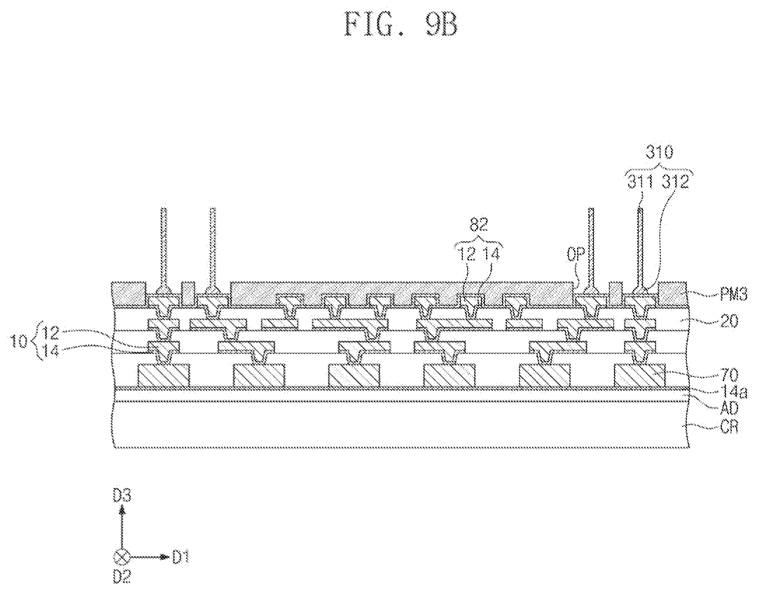

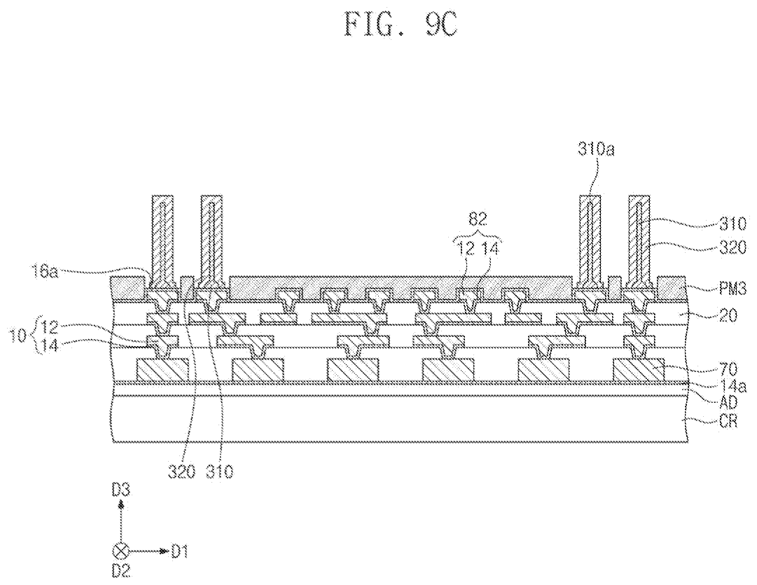

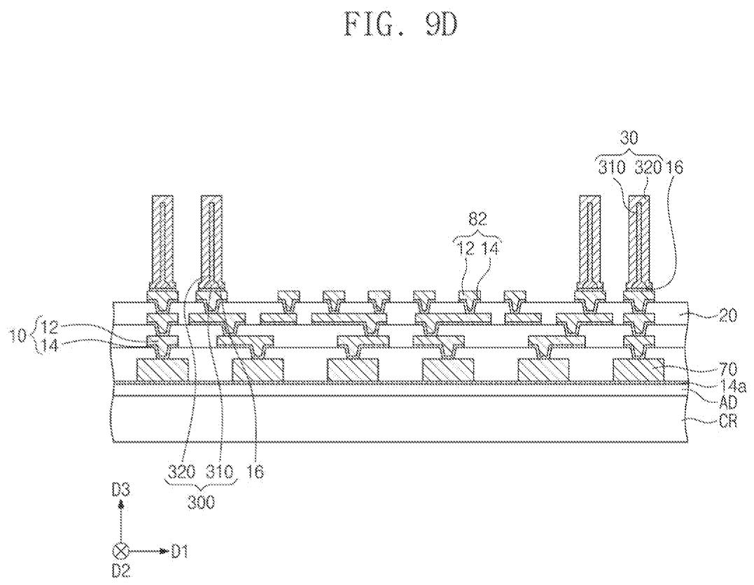

FIGS. 9A to 9D are cross-sectional views illustrating a method of manufacturing a semiconductor package according to example embodiments of the inventive concepts.

Referring to FIGS. 7D and 9A, a seed layer 16a may be formed on the top surface 1000a of the first redistribution substrate 1000. The seed layer 16a may cover the top surface 1000a of the first redistribution substrate 1000, top surfaces and side surfaces of the first upper pads 82, and top surfaces and side surfaces of the second upper pads 84. Next, a third photomask pattern PM3 may be formed to include openings OP exposing the top surfaces of the second upper pads 84. The third photomask pattern PM3 may cover the seed layer 16a which does not vertically overlap with the first upper pads 82 and the second upper pads 84. A thickness of the third photomask pattern PM3 may be a thickness capable of covering the top surfaces of the first upper pads 82.

Referring to FIG. 9B, the wire bonding process may be performed on the seed layer 16a provided on the top surfaces of the second upper pads 84. The second portion 312 of the wire 310 may be in contact with the seed layer 16a. The wire bonding process may be the same as that discussed in connection with FIGS. 7E and 7F.

Referring to FIG. 9C, a metal layer 320 covering the top surface 310a and the side surface of the wire 310 may be formed using the seed layer 16a as an electrode. The metal layer 320 may be locally and selectively formed on the top surface 310a and the side surface of the wire 310.

Referring to FIG. 9D, the third photomask pattern PM3 may be removed. The seed layer 16a may be removed using an etching process to form a seed pattern 16 (see FIG. 5). Next, the processes of FIGS. 7J to 7L and 2 may be performed to manufacture a semiconductor package.

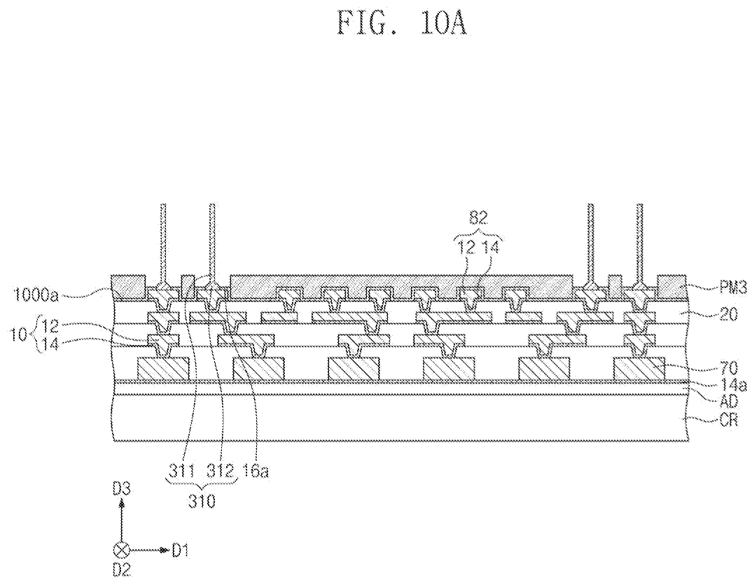

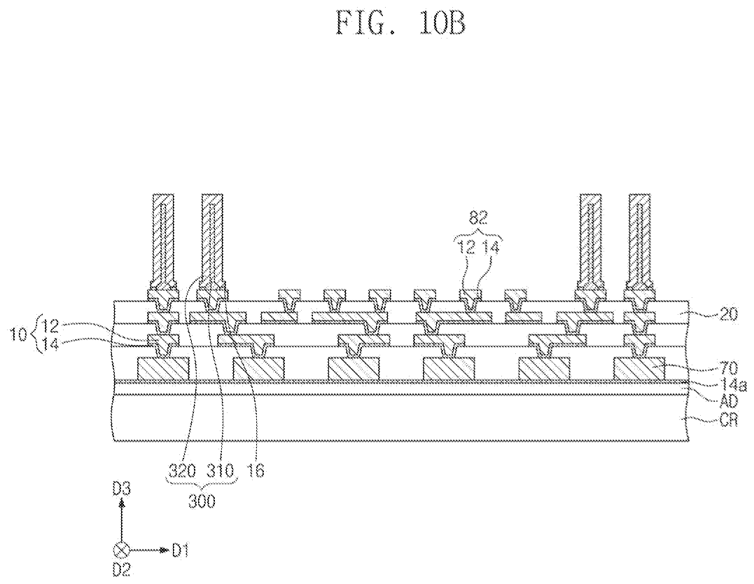

FIGS. 10A and 10B are cross-sectional views illustrating a method of manufacturing a semiconductor package according to example embodiments of the inventive concepts.

Referring to FIGS. 7D and 10A, the wire bonding process may be performed directly on the second upper pad 84. The wire bonding process may be the same as that discussed in connection with FIGS. 7E and 7F. Next, the seed layer 16a may be formed to cover the top surface 1000a of the first redistribution substrate 1000, a portion of the top surface and the side surface of the second upper pad 84 exposed from the wire 310, and the top surface and the side surface of the first upper pad 82. Next, the third photomask pattern PM3 may be formed to include an opening exposing a top surface of the seed layer 16a vertically overlapping with each of the second upper pads 84.

Referring to FIG. 10B, the metal layer 320 covering the top surface and the side surface of the wire 310 may be formed using the seed layer 16a as an electrode. The third photomask pattern PM3 may be removed, and the seed layer 16a may be removed using an etching process to form a seed pattern 16 (see FIG. 6). Next, the processes of FIGS. 7J to 7L may be performed to manufacture a semiconductor package.

It may be difficult to increase a height of a typical vertical conductive structure. For example, if a typical vertical conductive structure is formed using an electroplating process without a wire, a thick photoresist layer may be used as a mask pattern defining a space in which the typical vertical conductive structure will be formed. Alternatively, a height of a typical vertical conductive structure may be increased by processes using a plurality of photoresist layers, for example, a process of forming a first mask pattern, a process of forming a first vertical conductive structure, a process of forming a second mask pattern exposing the first vertical conductive structure, and a process of forming a second vertical conductive structure connected to the first vertical conductive structure. In these processes, a formation time of the typical vertical conductive structure may be increased, and a manufacturing cost thereof may be increased.

On the contrary, according to the embodiments of the inventive concepts, the height of the vertical conductive structure may be easily increased using the wire in the process, and the strength of the wire may be reinforced using the metal layer. In some embodiments, the metal layer may be formed by the electroplating process using the wire as an electrode, and thus the process of forming the metal layer may not use a photoresist. In certain embodiments, in the case in which the metal layer is formed using the seed layer, the wire and the seed layer may be connected to each other to function as an electrode, and thus the metal layer may be formed to a desired height by using a thin photoresist.

According to the embodiments of the inventive concepts, the vertical conductive structure may include the wire and the metal layer covering the side surface of the wire. The length of the wire may be adjusted in the process, and the metal layer may reinforce the strength of the wire. As a result, when the thickness of the semiconductor chip in the package is increased to improve heat dissipation characteristics, the height of the vertical conductive structure may be easily increased to improve the reliability of the semiconductor package.

While the embodiments of the inventive concepts have been particularly shown and described, it will be understood by one of ordinary skill in the art that variations in form and detail may be made therein without departing from the spirit and scope of the attached claims.

What is claimed is:

1. A semiconductor package comprising:
a first redistribution substrate;
a semiconductor chip on the first redistribution substrate; and
vertical conductive structures spaced apart from a side surface of the semiconductor chip,
wherein each of the vertical conductive structures comprises:
a wire; and
a metal layer covering a side surface of the wire,
wherein a top surface of the wire is exposed from the metal layer.

2. The semiconductor package of claim 1, wherein the wire and the metal layer include different metal materials.

3. The semiconductor package of claim 2, wherein the wire includes at least one of silver, gold, or aluminum, and the metal layer includes copper.

4. The semiconductor package of claim 1,
wherein the wire includes a first metal material,
wherein the metal layer includes a second metal material,
wherein the first metal material and the second metal material include the same material, and
wherein a grain size and a crystal direction of the first metal material are different from a grain size and a crystal direction of the second metal material.

5. The semiconductor package of claim 1,
wherein the wire includes: a first portion; and a second portion disposed at an end of the first portion and having a hemisphere shape, and
wherein a diameter of the hemisphere shape is greater than a width of the first portion.

6. The semiconductor package of claim 1,
wherein the first redistribution substrate comprises: an upper pad disposed on a top surface of the first redistribution substrate,
wherein the wire and the metal layer are in contact with the upper pad, and
wherein the metal layer and the upper pad include the same metal material.

7. The semiconductor package of claim 1, further comprising:
a seed pattern,
wherein the seed pattern is in contact with a bottom surface of the wire and a bottom surface of the metal layer.

8. The semiconductor package of claim 1, further comprising:
a seed pattern,
wherein the seed pattern is in contact with a bottom surface of the metal layer and a side surface of a lower portion of the wire and is spaced apart from a bottom surface of the wire.

9. The semiconductor package of claim 1, further comprising:
a molding member covering a top surface and a side surface of the semiconductor chip and a side surface of the metal layer,
wherein the molding member is spaced apart from the wire.

10. The semiconductor package of claim 9, further comprising:
a second redistribution substrate on the molding member,
wherein the first redistribution substrate comprises: a first insulating layer; and a first redistribution pattern in the first insulating layer,
wherein the second redistribution substrate comprises: a second insulating layer; and a second redistribution pattern in the second insulating layer, and
wherein each of the vertical conductive structures is connected to the first redistribution pattern and the second redistribution pattern.

11. The semiconductor package of claim 1, further comprising:
a molding member covering a top surface and a side surface of the semiconductor chip and a side surface of each of the vertical conductive structures,
wherein a top surface of each of the vertical conductive structures is exposed from the molding member.

12. A semiconductor package comprising:
a first redistribution substrate;
a semiconductor chip on the first redistribution substrate; and
vertical conductive structures disposed on the first redistribution substrate and spaced apart from a side surface of the semiconductor chip,
wherein each of the vertical conductive structures comprises:
a wire; and
a metal layer covering a side surface of the wire,
wherein a level of a top surface of the wire is substantially the same as a level of a top surface of the metal layer.

13. The semiconductor package of claim 12, further comprising:
a second redistribution substrate vertically spaced apart from the first redistribution substrate with the semiconductor chip interposed therebetween,
wherein the wire includes: a first portion extending in a line shape; and a second portion disposed at an end of the first portion and having a hemisphere shape, and
wherein the first portion is connected to the second redistribution substrate, and the second portion is connected to the first redistribution substrate.

14. The semiconductor package of claim 12, wherein a height of the wire is substantially equal to a height of the metal layer.

15. The semiconductor package of claim 12,
wherein the first redistribution substrate comprises an upper pad,
wherein the wire and the metal layer are in contact with the upper pad, and
wherein the metal layer and the upper pad include the same metal material.

16. The semiconductor package of claim 12, further comprising:
a seed pattern,
wherein the first redistribution substrate comprises an upper pad, and
wherein the wire and the metal layer are spaced apart from the upper pad with the seed pattern interposed therebetween.

17. The semiconductor package of claim 12, further comprising:
a seed pattern,
wherein the first redistribution substrate comprises an upper pad,
wherein the metal layer is spaced apart from the upper pad with the seed pattern interposed therebetween, and
wherein a lowermost portion of the wire is disposed below an uppermost portion of the seed pattern.

18. A semiconductor package comprising:
a first package; and
a second package on the first package,
wherein the first package comprises:
a first redistribution substrate;
a first semiconductor chip and vertical conductive structures on the first redistribution substrate, each of the vertical conductive structures comprising a wire and a metal layer covering a side surface of the wire;
a second redistribution substrate spaced apart from the first redistribution substrate with the first semiconductor chip and the vertical conductive structures interposed therebetween; and
a first molding member disposed between the first redistribution substrate and the second redistribution substrate and covering a top surface and a side surface of the first semiconductor chip and a side surface of the metal layer,
wherein the second package comprises:
a package substrate;
a second semiconductor chip on the package substrate; and
a second molding member covering a top surface of the package substrate and a top surface and a side surface of the second semiconductor chip,
wherein the wire includes: a first portion; and a second portion disposed at an end of the first portion,
wherein the first portion has a line shape of which a width is substantially constant as a height in a first direction perpendicular to a top surface of the first redistribution substrate increases, and the second portion has a shape of which a width decreases as a height in the first direction increases, and
wherein another end of the first portion is in contact with the second redistribution substrate, and the second portion is in contact with the first redistribution substrate.

19. The semiconductor package of claim 18, wherein a diameter of the second portion is greater than the width of the first portion.

20. The semiconductor package of claim 18, wherein the wire includes at least one of silver, gold, or aluminum, and the metal layer includes copper.
